(19) United States
(12) Patent Application Publication
(10) Pub. No.: US 2025/0273591 A1
(43) Pub. Date: Aug. 28, 2025

(54) ADDING SACRIFICIAL TRACES TO ABORB SIGNAL INTERFERENCE FROM HIGH SPEED AGGRESSOR TRACES

(71) Applicant: Sandisk Technologies, Inc., Milpitas, CA (US)

(72) Inventors: Uthayarajan A/L Rasalingam, Penang (MY); Bharath Radhakrishnan, Penang (MY); Chun Theng Loh, Penang (MY)

(21) Appl. No.: 18/585,866

(22) Filed: Feb. 23, 2024

(51) Int. Cl. H01L 23/552; G06F 30/3953; H01L 21/768; H01L 23/532

(52) U.S. Cl. CPC H01L 23/552; G06F 30/3953; H01L 21/768; H01L 23/53228

(57) ABSTRACT

A semiconductor package includes an integrated circuit having a first trace configured to convey a signal and a ground layer positioned on one side of the integrated circuit. A sacrificial trace is positioned between the ground layer and the first trace. The sacrificial trace absorbs electromagnetic signals emitted from the signal conveyed in the first trace. A method of manufacturing a semiconductor package that includes providing an integrated circuit that includes a first trace configured to convey a signal, positioning a ground layer on one side of the integrated circuit, and positioning a sacrificial trace between the ground layer and the first trace, where the sacrificial trace absorbs electromagnetic signals emitted from the signal conveyed in the first trace.

### BACKGROUND

Electronic technologies such as digital computers, video equipment, and telephone systems have facilitated increased productivity and reduced costs in processing information in most areas of business, science, and entertainment. The electronic systems often include integrated circuits, or semiconductor packages, that process signals. Semiconductor packages typically include a number of different semiconductor chips that process and store data. For example, a semiconductor package can include one or more integrated circuits and one or more memory dies. As demand for semiconductor packages increases, so do the demands for higher density, smaller size and higher performance. However, higher performance typically means faster integrated circuits and memory dies.

Accurate signal processing is important for proper performance. However, there are a number of factors that can impact the accuracy of signal processing. Oscillating signals are often affected by cross talk noise and signal interference, which in-turn typically cause various performance issues relating to signal quality and timing. The interference can become increasingly problematic in areas where signal transport lines, or traces, are densely situated. Conventional traces are often susceptible to cross talk noise that limits bit rate and produces noise. These adverse effects can interfere with critical functions, such as a high speed differential clock and a strobe component, among others. Traditionally, traces that are susceptible to interference are referred to as victims, and signal conductors that generate or propagate the noise are typically referred to as aggressors.

The distance between the aggressor and victim traces may affect the amount of potential noise, glitching, and other interference on the victim traces. Generally, the strength of the interference is proportional to a distance between the aggressor trace and a ground plane of the printed circuit board (PCB). Put another way, the closer the aggressor trace is to the ground plane, the smaller the interference that affects the victim traces. This reduction in incident electromagnetic interference (EMI) and electromagnetic fields (EMF) is due to the absorption of the electromagnetic fields by the ground plane. Modern PCB designs require very small trace separation for temperature performance considerations. Therefore it is very challenging to reduce the effects EMI and EMFs on victim traces.

What is needed is an approach that reduces electromagnetic interference and fields incident on victim traces in a manner that accommodates PCB density and temperature design requirements.

### SUMMARY

The present disclosure describes a semiconductor package includes an integrated circuit having a first trace configured to convey a signal and a ground layer positioned on one side of the integrated circuit. A sacrificial trace is positioned between the ground layer and the first trace. The sacrificial trace absorbs electromagnetic signals emitted from the signal conveyed in the first trace.

Accordingly, examples of the present disclosure describe a method of manufacturing a semiconductor package that includes providing an integrated circuit that includes a first trace configured to convey a signal, positioning a ground layer on one side of the integrated circuit, and positioning a sacrificial trace between the ground layer and the first trace, where the sacrificial trace absorbs electromagnetic signals emitted from the signal conveyed in the first trace.

Other examples describe a system that includes a means for providing an integrated circuit that includes a first trace configured to convey a signal, a means for positioning a ground layer on one side of the integrated circuit, and a means for positioning a sacrificial trace between the ground layer and the first trace, where the sacrificial trace absorbs electromagnetic signals emitted from the signal conveyed in the first trace.

This summary is provided to introduce a selection of concepts in a simplified form that are further described below in the Detailed Description. This summary is not intended to identify key features or essential features of the claimed subject matter, nor is it intended to be used to limit the scope of the claimed subject matter.

### BRIEF DESCRIPTION OF THE DRAWINGS

Non-limiting and non-exhaustive examples are described with reference to the following Figures.

FIG. 1 is a perspective, exploded view of a semiconductor package according to current solutions.

FIG. 2 is a cross-sectional view of a semiconductor package that includes sacrificial traces according to an example.

FIG. 3 is a flowchart of an example of a method of manufacturing a semiconductor package according to an example.

FIG. 4 is a block diagram of a system that includes a host device and a data storage device configured to generate a printed circuit board (PCB) design according to an example.

### DETAILED DESCRIPTION

In the following detailed description, references are made to the accompanying drawings that form a part hereof, and in which are shown by way of illustrations specific embodiments or examples. These aspects may be combined, other aspects may be utilized, and structural changes may be made without departing from the present disclosure. The following detailed description is therefore not to be taken in a limiting sense, and the scope of the present disclosure is defined by the appended claims and their equivalents.

As previously explained, memory and communication printed circuit board (PCB) designs have high speed requirements, such as high clock signals and peripheral component interconnect express (PCIe) interfaces. Accordingly, PCB signals are designed with traces that support high clock speed traces. Despite their utility, the high speed traces comprise aggressor traces that emit signals that cause noise and glitching on adjacent, victim traces. This problem is exacerbated when traces are designed in the high-density manner of modern semiconductor packages.

More particularly, the distance between the aggressor and victim traces may affect the amount of potential interference. Other factors may include PCB dielectric and ground routing techniques in the PCB designs. Although the strength of the noise or interference depend in part on the above factors (e.g., dielectric and routing considerations), they are proportionally equal to a length between the aggressor trace to the ground plane. Put another way, the closer the aggressor trace is to the ground plane, the smaller the interference that affects the victim traces. This reduction in incident EMI and EMF is due to the absorption of the electromagnetic fields by the ground plane. Modern PCB designs require very small trace separation for temperature performance considerations. Therefore it is very challenging to reduce the EMI and EMFs effects on victim traces.

In order to address the above, the present disclosure describes a method of designing a semiconductor package that reduces signal interference that is incident on the victim PCB traces by the high speed aggressor traces. Interference exposure to the victim trace is limited by adding a copper trace layer on top of a ground plane of the semiconductor package. The added trace layer may be oriented in a direction that is parallel to a length of the aggressor trace.

The reduction of noise and other interference is proportional to the size of the added trace. The added copper trace layer causes the ground plane to be closer to the aggressor trace. The closer proximity and orientation allow for more EMI and EMFs to be absorbed by the ground plane instead of the victim traces.

In an example, the added trace layer is added during the copper plating process. The copper plating process masks unwanted plating areas on the ground plane and leaves exposed only those target trace areas below the aggressor traces.

An illustrative thickness of the added trace layer is equal to about one half of the thickness of the ground plane. The thickness is defined by a first distance from a point at a bottom surface of the added trace layer to a top surface of a top layer of the PCB, minus a second distance defined by a distance between a top surface of the added layer to a bottom surface of an aggressor trace. The determined thickness brings the ground plane closer to the aggressor trace. The determined thickness depends on the number of PCB layers, as well as the respective thicknesses of the dialectic layer and the copper layer base.

Positioning the added trace layer below and parallel to the aggressor trace reduces the overall impact of interference. The inclusion and positioning of the added trace layer further allows designers to move traces closer to one another while still reducing EMI and EMF.

Accordingly, many technical benefits may be realized, including, but not limited to, reducing the signal interference that is incident on victim PCB traces by a high speed aggressor traces. The added trace layer causes the ground plane to be closer to the aggressor trace. The closer proximity and orientation allow for more EMI and EMFs to be absorbed by the ground plane instead of the victim traces. Positioning the added trace layer below and parallel to the aggressor trace reduces the overall impact of interference. The inclusion and positioning of the added trace layer further allows designers to move traces closer to one another while still reducing EMI and EMF.

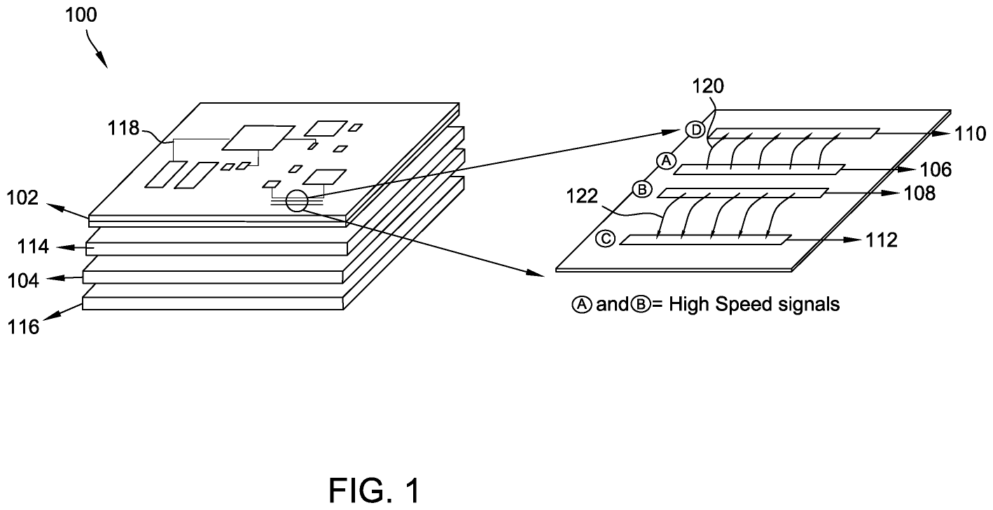

These benefits, along with other examples, will be shown and described in greater detail with respect to FIGS. 1-4.

FIG. 1 is a perspective, exploded view of a semiconductor package according to current solutions. The semiconductor package 100 includes multiple layers. For example, the semiconductor package includes a first layer 102, a second layer 114, a third layer 104 and a fourth layer 116.

In an example, the first layer is a signal layer and includes a solder mask 118. The third layer 104 is a ground layer that is sandwiched between two dielectric layers (e.g., the second layer 114 and the fourth layer 116). The semiconductor package 100 also includes a first trace 106 and a second trace 108, referred to here as aggressor traces. The semiconductor package 100 also includes a third trace 110 and a fourth trace 112, referred to as victim traces. Each of the traces may be at least partially exposed through the solder mask 118.

In an example, the aggressor traces are high-speed signal traces and cause EMI and EMFs to affect victim traces (e.g., the third trace 110 and the fourth trace 112). The EMI\EMF effects 120, 122 of the high-speed signals A and B along the first trace 106 and the second trace 108 will cause victim signals C and D to have noise or glitches.

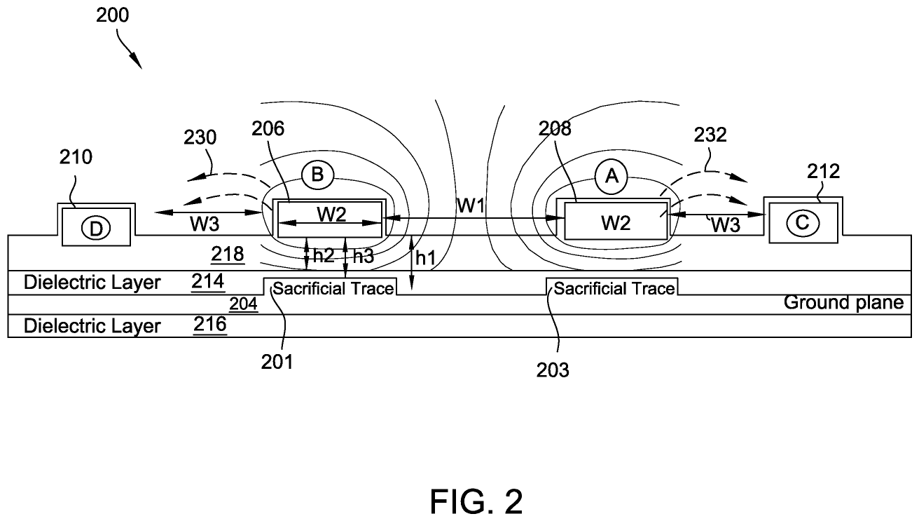

FIG. 2 is a cross-sectional view of a semiconductor package 200 that includes sacrificial traces 201, 203 according to an example. In one example, the semiconductor package 200 is similar to the semiconductor package 100 of FIG. 1. For example, the semiconductor package 200 includes a ground plane 204 sandwiched between dielectric layers 214, 216. A solder mask 218 and/or a signal layer is provided on a top surface of at least one of the dielectric layers 214.

As previously explained, the semiconductor package 200 includes sacrificial traces 201, 203. In an example, the sacrificial traces 201, 203 are positioned on or above a ground plane 204. For example, the sacrificial traces 201, 203 may be formed on a top surface of the ground plane 204. At least one dielectric layer 214 is provided over the sacrificial trace 201, 203. In such an example, a first portion of the dielectric layer 214 has a first thickness and a second portion (e.g., a portion that covers the sacrificial traces 201, 203) has a second thickness and/or follows a stairstep configuration of the sacrificial traces 201, 203.

In an example, the sacrificial traces 201, 203 are comprised of copper, copper plating or other material. The sacrificial traces 201, 203 are formed on the ground plane 204 as part of a copper plating process. However, in some examples, the sacrificial traces 201, 203 are non-transmission traces. For example, the sacrificial traces 201, 203 do not carry or transmit any transmission signals.

In an example, the signal layer of the semiconductor package 200 includes aggressor traces 206, 208. separated by a first width W1. The semiconductor package 200 also includes victim traces 210, 212 that are separated from the aggressor traces 206, 208 by a third width W3. However, in order to reduce EMI\EMF effects 230, 232 of high-speed signals A and B along the aggressor traces 206, 208 (and thereby reduce the risk of noise or glitches on victim signals C and D), the semiconductor package 200 includes sacrificial traces 201, 203.

The sacrificial traces 201, 203 are oriented parallel to lengths of aggressor traces 206, 208. In some examples, the sacrificial traces 201, 203 extend beneath the aggressor traces 206, 208 for the entire length of the aggressor traces 206, 208. In other example, the sacrificial traces 201, 203 extend parallel to lengths of the aggressor traces 206, 208 when the aggressor traces 206, 208 are adjacent or proximate to victim traces 210, 212.

For example, the sacrificial traces 201, 203 extend substantially along the entire widths (W2) and/or lengths of the aggressor traces 206, 208. In another example, the width and/or length of the sacrificial traces 201, 203 are greater than or less than the lengths and/or widths of the aggressor traces 206, 208.

Configuring the lengths of the sacrificial traces 201, 203 to match that of the aggressor traces 206, 208 function to absorb the interference along their horizontal dimensions to minimize EMI and EMFs 230, 232 otherwise incident on victim traces 210, 212. As previously described, the sacrificial traces 201, 203 are made of copper. Although copper is specifically mentioned, other materials may be used. Noise and other interference 230, 232 from the aggressor traces 206, 208 are reduced by including the sacrificial traces 201, 203 above the ground plane 204.

A distance W3 between the aggressor traces 206, 208 and the victim traces 210, 212 may affect the amount of potential interference. Other factors may include PCB dielectric and ground (GND) routing techniques in the PCB designs. Although the strength of the noise or interference 230, 232 depend in part on the above factors, they are typically proportionally equal to a length h1 between an aggressor trace 206 to the ground plane 204.

In general, the closer the aggressor trace 206 is to the ground plane 204, the smaller the interference effect 230, 232 on the victim traces 210, 212. The addition of the sacrificial traces 201, 203, which are raised or otherwise positioned on the ground plane 204 (e.g., a copper layer), function to shorten the distance h3 between the aggressor trace 206. This configuration causes a reduction in incident EMI and EMF 230, 232 due to absorption of the fields by the ground plane 204 (via sacrificial traces 201, 203).

In terms of FIG. 2, the thickness of the added, sacrificial trace 201 is shown as a distance between h1 minus h3. Put another way, the thickness of the sacrificial trace 201 equals a first distance (h1) defined by a point at the bottom surface of the added trace 201 to a top surface of the top layer 242 (e.g., solder mask) minus a second distance (h3) defined by a distance between a top surface of the added layer 201 to a bottom surface of the aggressor trace 206.

In another example, a thickness of the sacrificial traces 201, 203 is half of the thickness of the ground plane 204. For example, h1−h3=0.5×Ground Plane Thickness. Although a specific thickness is described, other thicknesses may be used. The determined thickness brings the ground plane 204 closer to the aggressor trace 206.

In examples, the values of h1 and h3 depend on a number of PCB layers, the thicknesses of the dialectic layers 214, 216 and the ground plane 204 (or the copper layer base), as well as a distance h2 between the aggressor trace 206 and a dielectric layer 214. While the sacrificial trace 201 is described in some examples as being a separate trace structure that is positioned above or on top of the ground plane 204, the sacrificial trace may also be considered a raised surface of the ground plane 204.

Because the sacrificial traces 201, 203 reduce the negative effects of EMI and EMF 230, 232, the distance W3 between the aggressor traces 206, 208 and the victim traces 210, 212 may be reduced when compared with current solutions in which sacrificial traces 201, 203 are not included. As such, additional space of the PCB may be freed or otherwise made available for other components and/or additional traces.

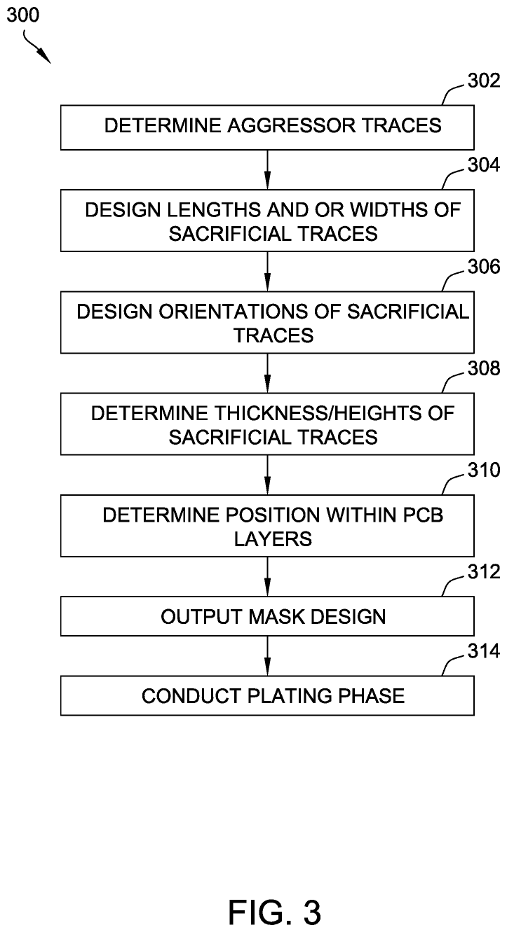

FIG. 3 is a flowchart of an example of a method 300 for manufacturing a semiconductor package according to an example. In an example, the method 300 may be used to manufacture or create the semiconductor package 100, 200 shown and described with respect to FIGS. 2 and 3. The method 300 includes adding a sacrificial trace layer below and parallel to an aggressor trace to reduce an overall impact of interference.

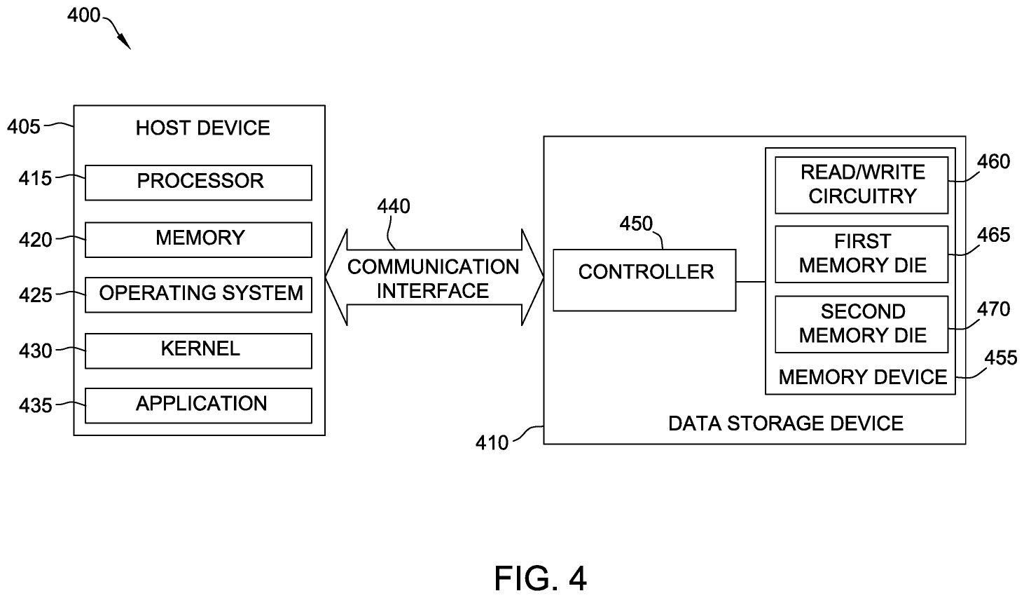

Turning more particularly to the flowchart, the method 300 includes determining at 302 one more aggressor traces in a PCB design. For example, a PCB design program executed by a computing system, such as the system 400 of FIG. 4, may be executed to determine the position and potential interference impact of aggressor traces on victim traces.

At 304, the method 300 includes designing lengths and/or widths of sacrificial traces. For example, the sacrificial trace 201 of FIG. 2 is designed to be the same length and width of the aggressor trace 206.

The orientations of the sacrificial traces of an example are determined at 306. For instance, the sacrificial trace 201 of FIG. 2 is designed to be in a direction parallel to an axis of the aggressor trace 206.

At 308, the method 300 includes determining a thickness, or height, or each sacrificial trace. For example, a thickness of a sacrificial trace 201 of FIG. 2 equals a first distance (h1) defined by a point at the bottom surface of the added trace 201 to a top surface of the top layer 242 minus a second distance (h3) defined by a distance between a top surface of the added layer 201 to a bottom surface of the aggressor trace 206. The thickness of an example is equal to about one half of the thickness of the ground plane.

The position of each sacrificial trace within the layers of the PCB package is determined at 310. For example, the sacrificial traces 201, 203 of FIG. 2 are positioned above a ground plane 204, which is sandwiched by dielectric layers 214, 216.

At 312, the method 300 may include generating an output design of a mask. The mask includes aggressor and victim traces, in addition to the sacrificial traces designed in 304-310 of the method 300. The mask may comprise a pattern transferring device that includes opaque areas that allow light to shine through according to the pattern of the designed mask.

At 314, the method 300 may include conducting a copper plating phase. The copper plating process of an example deposits the copper comprising the sacrificial traced onto the ground layer, while masking unwanted plating areas on the ground plane and leaving exposed only those target trace areas below the aggressor traces.

FIG. 4 is a block diagram of a system 400 that includes a host device 405 and a data storage device 410 configured to generate a PCB design according to an example. In another example, the system 400 can include one or more semiconductor packages that implement or use sacrificial traces as described herein. As shown, the host device 405 includes a processor 415 and a memory 420 (e.g., main memory). The memory 420 may include or otherwise be associated with an operating system 425, a kernel 430 and/or an application 435.

The processor 415 can execute various instructions, such as, for example, instructions from the operating system 425 and/or the application 435. The processor 415 may include circuitry such as a microcontroller, a Digital Signal Processor (DSP), an Application-Specific Integrated Circuit (ASIC), a Field Programmable Gate Array (FPGA), hard-wired logic, analog circuitry and/or various combinations thereof. In an example, the processor 415 may include a System on a Chip (SoC).

In an example, the memory 420 can be used by the host device 405 to store data used, or otherwise executed by, the processor 415. Data stored in the memory 420 may include instructions provided by the data storage device 410 via a communication interface 440. The data stored in the memory 420 may also include data used to execute instructions from the operating system 425 and/or one or more applications 435. The memory 420 may be a single memory or may include multiple memories, such as, for example one or more non-volatile memories, one or more volatile memories, or a combination thereof.

In an example, the operating system 425 may create a virtual address space for the application 435 and/or other processes executed by the processor 415. The virtual address space may map to locations in the memory 420. The operating system 425 may also include or otherwise be associated with a kernel 430. The kernel 430 may include instructions for managing various resources of the host device 405 (e.g., memory allocation), handling read and write operations and so on.

The communication interface 440 communicatively couples the host device 405 and the data storage device 410. The communication interface 440 may be a Serial Advanced Technology Attachment (SATA), a PCI express (PCIe) bus, a Small Computer System Interface (SCSI), a Serial Attached SCSI (SAS), Ethernet, Fibre Channel, or W1-Fi. As such, the host device 405 and the data storage device 410 need not be physically co-located and may communicate over a network such as a Local Area Network (LAN) or a Wide Area Network (WAN), such as the internet. In addition, the host device 405 may interface with the data storage device 410 using a logical interface specification such as Non-Volatile Memory express (NVMe) or Advanced Host Controller Interface (AHCI).

The data storage device 410 may include a controller 450 and a memory device 455. The controller 450 may be communicatively coupled to the memory device 455. In an example, the memory device 455 includes one or more memory dies (e.g., first memory die 465 and second memory die 470). Although memory dies are specifically mentioned, the memory device 455 may include any non-volatile memory device, storage device, storage elements or storage medium including NAND flash memory cells and/or NOR flash memory cells.

The memory cells can take the form of solid-state (e.g., flash) memory cells and can be one-time programmable, few-time programmable, or many-time programmable. Additionally, the memory cells may be single-level cells (SLCs), multi-level cells (MLCs), triple-level cells (TLCs), quad-level cells (QLCs), penta-level cells (PLCs), and/or use any other memory technologies. The memory cells may be arranged in a two-dimensional configuration or a three-dimensional configuration.

In some examples, the data storage device 410 may be attached to or embedded within the host device 405. In another example, the data storage device 410 may be implemented as an external device or a portable device that can be communicatively or selectively coupled to the host device 405. In yet another example, the data storage device 410 may be a component (e.g., a solid-state drive (SSD)) of a network accessible data storage system, a network-attached storage system, a cloud data storage system, and the like.

As indicated above, the memory device 455 of the data storage device 410 may include a first memory die 465 and a second memory die 470. Although two memory dies are shown, the memory device 455 may include any number of memory dies (e.g., one memory die, two memory dies, eight memory dies, or another number of memory dies).

The memory device 455 may also include support circuitry. In an example, the support circuitry includes read/write circuitry 460. The read/write circuitry 460 supports the operation of the memory dies of the memory device 455. Although the read/write circuitry 460 is depicted as a single component, the read/write circuitry 460 may be divided into separate components, such as, for example, read circuitry and write circuitry. The read/write circuitry 460 may be external to the memory dies of the memory device 455. In another example, one or more of the memory dies may include corresponding read/write circuitry 460 that is operable to read data from and/or write data to storage elements within one individual memory die independent of other read and/or write operations on any of the other memory dies.

The data storage device 410 and/or the memory device 455 may be arranged in or otherwise associated with a hierarchy. For example, the memory device 455 may include multiple memory dies, and each memory die may include multiple planes and quadrants. Further each plane and/or quadrant may include multiple memory blocks. Each memory block may include multiple wordlines. Each physical (or logical portion) of the data storage device 400 may be referred to as a portion and one or more portions may be more susceptible to failures (e.g., data retention failures, read disturbs, program disturbs) when compared with other portions. This will be explained in greater detail below.

Each of the first memory die 465 and the second memory die 470 may include one or more memory blocks. In an example, each memory block includes one or more memory cells. A block of memory cells is the smallest number of memory cells that are physically erasable together. In an example and for increased parallelism, each of the blocks may be operated or organized in larger blocks or metablocks. For example, one block from different planes of memory cells may be logically linked together to form a metablock.

Based on the above, examples of the present disclosure describe a semiconductor package that includes an integrated circuit having a first trace configured to convey a signal and a ground layer positioned on one side of the integrated circuit. A sacrificial trace is positioned between the ground layer and the first trace. The sacrificial trace absorbs electromagnetic signals emitted from the signal conveyed in the first trace.

Examples also describe a method of manufacturing a semiconductor package that includes providing an integrated circuit that includes a first trace configured to convey a signal, positioning a ground layer on one side of the integrated circuit, and positioning a sacrificial trace between the ground layer and the first trace, where the sacrificial trace absorbs electromagnetic signals emitted from the signal conveyed in the first trace.

Other examples describe a system comprising a means for providing an integrated circuit that includes a first trace configured to convey a signal, a means for positioning a ground layer on one side of the integrated circuit, and a means for positioning a sacrificial trace between the ground layer and the first trace, where the sacrificial trace absorbs electromagnetic signals emitted from the signal conveyed in the first trace.

The description and illustration of one or more aspects provided in the present disclosure are not intended to limit or restrict the scope of the disclosure in any way. The aspects, examples, and details provided in this disclosure are considered sufficient to convey possession and enable others to make and use the best mode of claimed disclosure.

The claimed disclosure should not be construed as being limited to any aspect, example, or detail provided in this disclosure. Regardless of whether shown and described in combination or separately, the various features (both structural and methodological) are intended to be selectively rearranged, included or omitted to produce an embodiment with a particular set of features. Having been provided with the description and illustration of the present application, one skilled in the art may envision variations, modifications, and alternate aspects falling within the spirit of the broader aspects of the general inventive concept embodied in this application that do not depart from the broader scope of the claimed disclosure.

Aspects of the present disclosure have been described above with reference to a block diagram of a method. It will be understood that each block or combinations of blocks in the block diagram may be combined and/or performed in any order.

References to an element herein using a designation such as “first,” “second,” and so forth does not generally limit the quantity or order of those elements. Rather, these designations may be used as a method of distinguishing between two or more elements or instances of an element. Thus, reference to first and second elements does not mean that only two elements may be used or that the first element precedes the second element. Additionally, unless otherwise stated, a set of elements may include one or more elements.

Terminology in the form of “at least one of A, B, or C” or “A, B, C, or any combination thereof” used in the description or the claims means “A or B or C or any combination of these elements.” For example, this terminology may include A, or B, or C, or A and B, or A and C, or A and B and C, or 2A, or 2B, or 2C, or 2A and B, and so on. As an additional example, “at least one of: A, B, or C” is intended to cover A, B, C, A-B, A-C, B-C, and A-B-C, as well as multiples of the same members. Likewise, “at least one of: A, B, and C” is intended to cover A, B, C, A-B, A-C, B-C, and A-B-C, as well as multiples of the same members.

Similarly, as used herein, a phrase referring to a list of items linked with “and/or” refers to any combination of the items. As an example, “A and/or B” is intended to cover A alone, B alone, or A and B together. As another example, “A, B and/or C” is intended to cover A alone, B alone, C alone, A and B together, A and C together, B and C together, or A, B, and C together.

What is claimed is:

1. A semiconductor package, comprising:
an integrated circuit that includes a first trace configured to convey a signal;
a ground layer positioned on one side of the integrated circuit; and
a sacrificial trace positioned between the ground layer and the first trace, wherein the sacrificial trace absorbs electromagnetic signals emitted from the signal conveyed in the first trace.

2. The semiconductor package of claim 1, wherein the sacrificial trace has the same dimensions as the first trace.

3. The semiconductor package of claim 1, wherein the sacrificial trace is comprised of copper.

4. The semiconductor package of claim 1, wherein the first trace is an aggressor trace and wherein the integrated circuit further comprises a victim trace adjacent the aggressor trace.

5. The semiconductor package of claim 1, wherein a thickness of the sacrificial trace is configured to equal one half a thickness of the ground layer.

6. The semiconductor package of claim 1, wherein a length of the sacrificial trace is positioned parallel to a length of the first trace.

7. The semiconductor package of claim 1, wherein a length of the sacrificial trace is equal to a length of the first trace.

8. The semiconductor package of claim 1, wherein the sacrificial trace is a non-transmission trace.

9. The semiconductor package of claim 1, wherein the sacrificial trace is constructed during a copper plating phase.

10. A method of manufacturing a semiconductor package, the method comprising:
providing an integrated circuit that includes a first trace configured to convey a signal;
positioning a ground layer on one side of the integrated circuit; and
positioning a sacrificial trace between the ground layer and the first trace, wherein the sacrificial trace absorbs electromagnetic signals emitted from the signal conveyed in the first trace.

11. The method of claim 10, further comprising configuring the sacrificial trace to have the same dimensions as the first trace.

12. The method of claim 10, wherein positioning the sacrificial trace further comprising generating the sacrificial trace during a copper plating phase.

13. The method of claim 10, further comprising configuring a thickness of the sacrificial trace to be equal to about one half of a thickness of the ground layer.

14. The method of claim 10, further comprising orienting a length of the sacrificial trace to be parallel to a length of the first trace.

15. The method of claim 10, further comprising configuring a length of the sacrificial trace to be equal to a length of the first trace.

16. A system comprising:
a means for providing an integrated circuit that includes a first trace configured to convey a signal;
a means for positioning a ground layer on one side of the integrated circuit; and
a means for positioning a sacrificial trace between the ground layer and the first trace, wherein the sacrificial trace absorbs electromagnetic signals emitted from the signal conveyed in the first trace.

17. The system of claim 16, further comprising a means for configuring the sacrificial trace to have the same dimensions as the first trace.

18. The system of claim 16, further comprising a means for generating the sacrificial trace during a copper plating phase.

19. The system of claim 16, further comprising a means for configuring a thickness of the sacrificial trace to be equal to about one half of a thickness of the ground layer.

20. The system of claim 16, further comprising a means for orienting a length of the sacrificial trace to be parallel to a length of the first trace.
